(19) United States
(12) Patent Application Publication
(10) Pub. No.: US 2022/0140035 A1
(43) Pub. Date: May 5, 2022

(54) FLEXIBLE DISPLAY

(71) Applicant: Wuhan China Star Optoelectronics Semiconductor Display Technology Co., Ltd., Wuhan, Hubei (CN)

(72) Inventor: Kai HU, Wuhan, Hubei (CN)

(73) Assignee: Wuhan China Star Optoelectronics Semiconductor Display Technology Co., Ltd., Wuhan, Hubei (CN)

(21) Appl. No.: 17/254,358

(22) PCT Filed: Jun. 16, 2020
(86) PCT No.: PCT/CN2020/096238

§ 371 Date: Dec. 21, 2020

(30) Foreign Application Priority Data
May 12, 2020 (CN) 202010395333.4

(51) Int. Cl. H01L 27/32; G09F 9/30; H01L 29/786

(52) U.S. Cl. CPC H01L 27/3262; H01L 27/3265; H01L 27/3276; H01L 29/78696; H01L 29/78645; H01L 29/78618; G09F 9/301

(57) ABSTRACT

A flexible display is provided. Each of a unit driving circuit of the flexible display includes a driving transistor and a reset capacitor. The reset capacitor includes a first reset electrode and a second reset electrode. The first reset electrode is arranged on a side of a gate of the driving transistor facing a source and a drain, and the second reset electrode is the gate or is electrically connected to the gate. The flexible display includes a metal interconnection layer formed around a transparent portion, and the metal interconnection layer is electrically connected to the first reset electrode.

### FIELD OF INVENTION

The present application relates to the field of flexible displays, and in particular to a flexible display.

### BACKGROUND OF INVENTION

At present, although hole-digging screens, which are mainstream in the market, have increased screen-to-body ratios, a hole-digging design makes a display effect of a screen worse at low grayscale levels. For example, a horizontal split screen phenomenon appears, caused by a difference in an array structure at position of a hole; a mura appears near a position of a camera hole, also known as O-cut mura; and unevenness of color and brightness occurs due to poor driving compensation capabilities at low grayscale levels. These situations are all related to a voltage compensation of a driver thin film transistor (DTFT). For example, a discontinuity of initial voltage level due to the hole-digging results in a split-screen phenomenon.

### SUMMARY OF INVENTION

### Technical Problem

Accordingly, it is an object of the present application to provide a flexible display capable of effectively improving color unevenness, brightness unevenness, and O-cut mura phenomenon at low grayscale levels of a hole-digging screen.

### Technical Solutions

The present application provides a flexible display. The flexible display includes a substrate and a plurality of sub-pixels arranged on the substrate, wherein each of the sub-pixels is provided with a unit driving circuit, each of the unit driving circuit includes a driving transistor and a reset capacitor, each of the driving transistor includes a gate, a channel layer, a source, and a drain, the reset capacitor includes a first reset electrode and a second reset electrode arranged oppositely, the reset electrode is arranged on a side of the gate facing the source and the drain, and the second reset electrode is the gate or is electrically connected to the gate, and wherein the flexible display includes a transparent portion and a metal interconnection layer formed in an interconnection region around the transparent portion, and the metal interconnection layer is electrically connected to the first reset electrode of the unit driving circuit of each of the sub-pixels positioned in the interconnection region.

In an embodiment, the metal interconnection layer is disposed on a side of the driving transistor away from the substrate, and is electrically connected to the first reset electrode of the unit driving circuit of each of the sub-pixels positioned in the interconnection region through a via hole.

In an embodiment, the driving transistor is a dual-gate thin film transistor, the first reset electrode is a top gate of the dual-gate thin film transistor, and the second reset electrode is a bottom gate of the dual-gate thin film transistor.

In an embodiment, the bottom gate is positioned between the top gate and the channel layer.

In an embodiment, the source and the drain are positioned between the metal interconnection layer and the top gate.

In an embodiment, the metal interconnection layer is provided on a same level as the source and the drain of the driving transistor.

In an embodiment, the channel layer is positioned between the top gate and the bottom gate.

In an embodiment, the reset capacitor is a storage capacitor electrically connected to the driving transistor, and the first reset electrode is an upper electrode plate of the storage capacitor.

In an embodiment, the second reset electrode is the gate, and the gate is a lower electrode plate of the storage capacitor.

In an embodiment, the upper electrode plate of the storage capacitor is positioned between the gate and the source and the drain.

In an embodiment, the upper electrode plate of the storage capacitor is positioned on a same level as the source and the drain.

In an embodiment, the second reset electrode is a lower electrode plate of the storage capacitor, and the lower electrode plate of the storage capacitor is electrically connected to the gate.

In an embodiment, the upper electrode plate of the storage capacitor is positioned on a same level as the source and the drain, and the lower electrode plate of the storage capacitor is positioned on a same level as the gate.

In an embodiment, the metal interconnection layer includes a metal grid pattern, and an orthographic projection of the metal grid pattern on a plane of a power voltage line overlaps a pattern formed by the power voltage line.

In an embodiment, the metal grid pattern includes a plurality of vertices and a plurality of connection lines connected between adjacent two of the vertices, the vertices are distributed in an array, and the vertices are arranged in a zigzag shape in a first direction, and are arranged in a straight line in a second direction.

In an embodiment, each of the vertices of the metal grid pattern is electrically connected to one of the first reset electrode.

In an embodiment, connection lines and a reset voltage line are manufactured by a same process and have a same line width.

### Beneficial Effect

Compared with the conventional art, the flexible display provided by the present application links plates of the reset capacitors of the multiple unit driving circuits into a grid structure by providing a metal interconnection layer. In this way, a same reset voltage can be applied to the driving transistors of different sub-pixels, and a difference in a reset gate voltage of the driving transistors caused by a hole-digging of a screen can be reduced, and brightness and chromaticity differences of a display screen can be effectively reduced. Since the reset voltages of the connected driving transistors are equal everywhere, no new defects will be caused when the reset voltage is adjusted, so that the reset voltage has a greater adjustment range, which can effectively improve the quality of the display screen.

### BRIEF DESCRIPTION OF FIGURES

In order to illustrate the technical solutions of the present application or the related art in a clearer manner, the drawings desired for the present application or the related art will be described hereinafter briefly. Obviously, the following drawings merely relate to some embodiments of the present application, and based on these drawings, a person skilled in the art may obtain the other drawings without any creative effort.

FIG. 1 is a schematic plane view and a partially enlarged schematic view of a flexible display according to an embodiment of the present application.

FIG. 2 is an equivalent circuit diagram of a unit driving circuit of the flexible display of FIG. 1.

FIG. 3 is a schematic partial cross-sectional view of the flexible display of FIG. 1.

FIG. 4 is a schematic top view of a power voltage line and a metal interconnection layer of the flexible display of FIG. 1.

FIG. 5 is a schematic partial cross-sectional view of the flexible display according to another embodiment of the present application.

FIG. 6 is a schematic partial cross-sectional view of the flexible display according to yet another embodiment of the present application.

FIG. 7 is an equivalent circuit diagram of the flexible display of FIG. 6.

FIG. 8 is a schematic partial cross-sectional view of the flexible display according to yet another embodiment of the present application.

### DETAILED DESCRIPTION OF EMBODIMENTS

The following content combines with the drawings and the embodiment for describing the present application in detail. It is obvious that the following embodiments are merely some embodiments of the present application, but not all the embodiments. Based on the embodiments in the present application, for the skilled persons of ordinary skill in the art without creative effort, the other embodiments obtained thereby are still covered by the present application.

In the description of the present invention, it is to be understood that the terms such as “center”, “upper”, “lower”, “left”, “right”, “vertical”, “horizontal”, “inside”, “outside”, etc., the orientation or positional relationship of the indications is based on the orientation or positional relationship shown in the drawings, and is merely for the convenience of the description of the invention and the simplified description, rather than indicating or implying that the device or component referred to has a specific orientation, in a specific orientation. The construction and operation are therefore not to be construed as limiting the invention. In addition, the terms “first”, “second”, and “third” are used for descriptive purposes only, and cannot be understood as indicating or implying relative importance.

Transistors used in all the embodiments of the present application can be thin film transistors or field effect transistors or other devices with same characteristics. Since a source and a drain of a transistor used here are symmetrical, the source and the drain are interchangeable. In the embodiments of the present application, in order to distinguish two electrodes of the transistor except a gate, one of the electrodes is called the source and the other is called the drain. According to a configuration in the figure, it is stipulated that a middle end of a switching transistor is the gate, a signal input end is the source, and an output end is the drain. In addition, the transistors used in the embodiments of the present application can include P-type transistors and/or N-type transistors. The P-type transistor is turned on when the gate is at low level and is turned off when the gate is at high level. The N-type transistor is turned on when the gate is at high level and is turned off when the gate is at low level.

The present application provides a flexible display 100, which can be used in wearable devices such as smart bracelets, smart watches, virtual reality (VR) devices, mobile phones, e-books and e-papers, televisions, personal computers, foldable and rollable flexible display devices, and lighting devices, etc. The flexible display 100 can be an organic light-emitting diode (OLED) display panel, a quantum dot organic light-emitting diode (QLED) display panel, and the like.

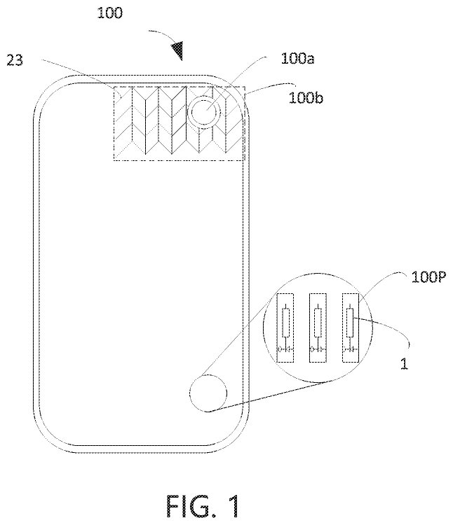

Refer to FIGS. 1 to 3, where FIG. 1 is a schematic plane view and a partially enlarged schematic view of a flexible display according to an embodiment of the present application. In FIG. 1, only a few sub-pixels and unit driving circuits of the flexible display are schematically shown.

The flexible display 100 includes a substrate 10, a driving circuit layer 20 disposed on the substrate 10, and a light-emitting layer 30 electrically connected to the driving circuit layer 20. The substrate 10 can be a double-layered polyimide flexible substrate. The light-emitting layer 30 includes an anode, a hole injection layer, a hole transport layer, a luminous layer, an electron transport layer, a cathode, etc., which are sequentially stacked. Although not shown, the flexible display 100 can also include components such as a thin film encapsulation layer.

The flexible display 100 can be divided into a display region AA and a non-display region NAA. The flexible display 100 includes the substrate 10 and a plurality of sub-pixels 100P disposed on the substrate 10 in the display region AA. Each of the sub-pixels 100P is provided with a unit driving circuit 1. The driving circuit layer 20 consists of the unit driving circuit 1. The unit driving circuit 1 can also be referred to as a pixel compensation circuit. Each of the unit driving circuit 1 includes a driving transistor DTFT and a reset capacitor 20C. The driving transistor DTFT refers to a transistor that drives a light-emitting unit, such as a transistor of an organic light-emitting diode, which is connected in series with a light-emitting device in the sub-pixel 100P, and a current flowing through the light-emitting device also all flows through a corresponding driving transistor DTFT. The reset capacitor 20C is configured to reset the driving transistor DTFT. The reset capacitor 20C includes a first reset electrode 21 and a second reset electrode 22 arranged oppositely. The first reset electrode 21 is arranged on a side of the gate facing the source and the drain. It can also be said that the first reset electrode 21 is arranged on a side of the gate away from the substrate 10. The first reset electrode 21 is arranged on the side of the gate facing the source and the drain. The first reset electrode 21 is electrically connected to a reset voltage line. The reset voltage line is configured to provide a reset signal. In an embodiment, the second reset electrode 22 is a gate. In another embodiment, the second reset electrode 22 is electrically connected to the gate.

The unit driving circuit 1 can be a pixel compensation circuit in the conventional art such as 4T1C, 5T1C, 7T1C, etc. In the following, the technical solution of the present application is illustrated by taking the unit driving circuit 1 as a 7T1C compensation circuit.

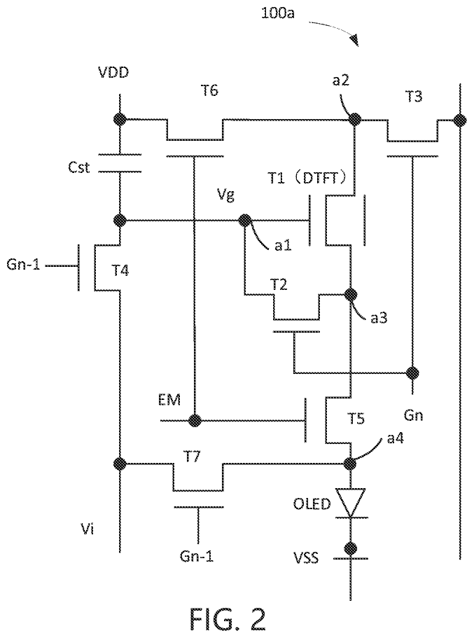

Refer to FIG. 2, the unit driving circuit 1 includes a first transistor T1, a second transistor T2, a third transistor T3, a fourth transistor T4, a fifth transistor T5, a sixth transistor T6, a seventh transistor T7, a storage capacitor Cst, and a light-emitting device D.

A top gate of the first transistor T1 is electrically connected to a first node a1, a bottom gate is floating, a source of the first transistor T1 is electrically connected to a second node a2, and a drain of the first transistor T1 is electrically connected to a third node a3.

A gate of the second transistor T2 is electrically connected to a first scan signal, a source of the second transistor T2 is electrically connected to the first node a1, and a drain of the second transistor T2 is electrically connected to the third node a3.

A gate of the third transistor T3 is electrically connected to the first scan signal, a source of the third transistor T3 is electrically connected to a data signal DATA, and a drain of the third transistor T3 is electrically connected to the second node a2. The first scan signal is provided by a gate line Gn of a current stage. The data signal is provided by a data line.

A gate of the fourth transistor T4 is electrically connected to a second scan signal, a source of the fourth transistor T4 is electrically connected to a low level Vi, and a drain of the fourth transistor T4 is electrically connected to the first node a1. The low level is provided by the reset voltage line. The second scan signal is provided by a gate line Gn−1 of a previous stage.

A gate of the fifth transistor T5 is electrically connected to a light-emitting signal EM, a source of the fifth transistor T5 is electrically connected to the third node a3, and a drain of the fifth transistor T5 is electrically connected to a fourth node a4.

A gate of the sixth transistor T6 is electrically connected to the light-emitting signal EM, a source of the sixth transistor T6 is electrically connected to a first power signal VDD, and a drain of the sixth transistor T6 is electrically connected to the second node a2. The first power signal VDD is provided by a power voltage line.

A gate of the seventh transistor T7 is electrically connected to the second scan signal, a source of the seventh transistor T7 is electrically connected to the low level Vi, and a drain of the seventh transistor T7 is electrically connected to the fourth node a4. The low level is provided by the reset voltage line, and the second scan signal is provided by the gate line Gn−1 of the previous stage.

A first end of the storage capacitor Cst is electrically connected to the first node a1, and a second end of the first capacitor is electrically connected to the first power signal.

An anode end of the light-emitting device D is electrically connected to the fourth node a4, and a cathode end of the light-emitting device D is electrically connected to a second power signal. The second power signal is a ground signal.

The first transistor T1 is the driving transistor DTFT of the unit driving circuit 1.

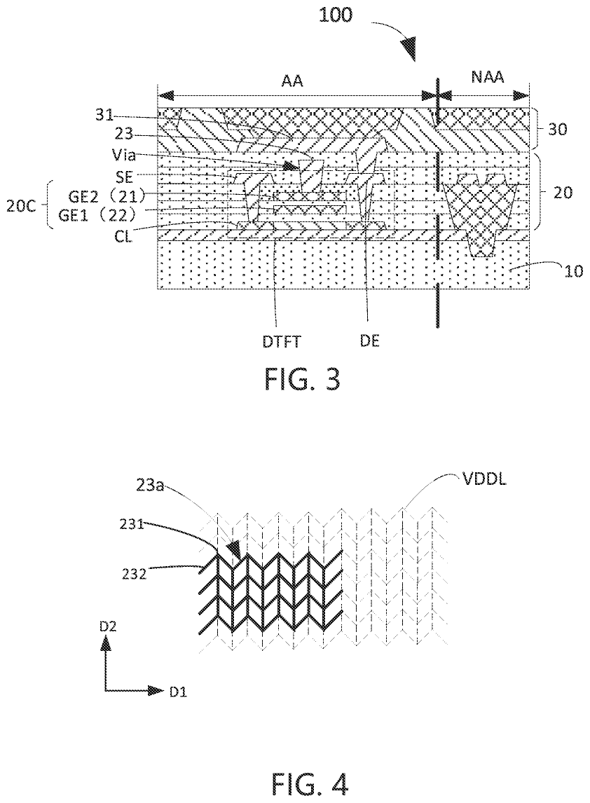

Refer to FIG. 3 again, in the present embodiment, each of the driving transistor DTFT is a dual-gate thin film transistor. The driving transistor DTFT includes a channel layer CL, a first gate GE1, that is, a bottom gate of the driving transistor DTFT, a second gate GE2, that is, a top gate of the driving transistor DTFT, and a source SE and a drain DE, which are stacked in sequence. The layers are insulated from each other by an insulation layer. The first reset electrode 21 is the top gate of the dual-gate thin film transistor, that is, the second gate GE2. The second reset electrode 22 is the bottom gate of the dual-gate thin film transistor, that is, the first gate GE1.

The flexible display 100 includes a transparent portion 100a and a metal interconnection layer 23 formed in an interconnection region 100b around the transparent portion 100a. A photosensitive element, such as a front camera, etc., is arranged under the transparent portion 100a. In other words, the flexible display 100 is a full screen with a hole-digging. An area and a shape of the interconnect region 100b can be set according to actual conditions, as long as it can solve problems of color unevenness, brightness unevenness, and O-cut mura in the grayscale level near the transparent portion 100a. In other embodiments of the present application, the interconnection region 100b can be an entire surface of the flexible display 100. The metal interconnection layer 23 is electrically connected to the first reset electrode 21 of the unit driving circuit 1 of the sub-pixel 100P positioned in the interconnection region 100b, that is, the second gate GE2.

The present application does not limit a position of the metal interconnection layer 23. In an embodiment, in order to prevent from interference, the metal interconnection layer 23 is disposed on a side of the driving transistor DTFT away from the substrate 10, and is connected to the first reset electrode 21, that is, the second gate GE2, of the unit driving circuit 1 of the sub-pixel 100P positioned in the interconnection region 100b through a via hole. In other words, the metal interconnection layer 23 is added between the source SE and the drain DE of the driving transistor DTFT and the anode 31 of the light-emitting layer 30. The metal interconnection layer 23 is insulated from the source SE, the drain DE, and the anode 31 by an insulation layer, the insulation layer is a planarization layer, for example. From a vertical direction in the figure, the first gate GE1 is positioned between the second gate GE2 and the channel layer CL. The source SE and the drain DE are positioned between the metal interconnection layer 23 and the second gate GE2. In other embodiments, the metal interconnection layer 23 can also be provided on a same level as the source SE and the drain DE of the driving transistor DTFT.

The present application does not limit a shape of the metal interconnection layer 23. In order to ensure an aperture ratio of the flexible display 100, the metal interconnection layer 23 includes a metal grid pattern 23a. Refer to FIG. 4, the metal grid pattern 23a includes a plurality of vertices 231 and a plurality of connection lines 231 connected between adjacent two of the vertices 231, the vertices 231 are distributed in an array, and the vertices 231 are arranged in a zigzag shape in a first direction D1, and are arranged in a straight line in a second direction D2. Each of the vertices 231 of the metal grid pattern 23a can be electrically connected to one of the first reset electrode 21.

In an embodiment, an orthographic projection of the metal grid pattern 23a on a plane of the power voltage line VDDL overlaps a pattern formed by the power voltage line VDDL. For example, a distance between adjacent two of the vertices 231 ranges from 20 microns to 50 microns. In an embodiment, the connection lines 231 and the reset voltage line are manufactured by a same process and have a same line width. For example, the line width of the connection lines 231 ranges from 1 microns to 3 microns.

In addition, the metal grid pattern 23a is electrically connected to the first reset electrode 21 through a metal connection part positioned in the via hole. The metal grid pattern 23a and the metal connection part are integrated and can be formed in a same manufacturing process.

The present application also does not limit materials of the metal interconnection layer 23. The material can use a same metal material as the gate, the source, and the drain of the driving transistor DTFT, such as molybdenum, aluminum, chromium, etc., or a transparent conductive material, such as indium tin oxide.

When the gate line Gn−1 is turned on and the reset voltage is input, the driving transistors DTFT of the unit driving circuits 1 of the sub-pixels 100P in a same row controlled by a GOA are reset at the same time, and multiple the driving transistors DTFT of the unit driving circuits 1 electrically connected to each other through the metal interconnection layer 23 are applied with a same reset voltage.

Compared with the conventional art, the flexible display provided by the present application links plates of the reset capacitors of the multiple unit driving circuits into a grid structure by providing the metal interconnection layer. In this way, the same reset voltage can be applied to the driving transistors of different sub-pixels, and a difference in a reset gate voltage of the driving transistors caused by the hole-digging of a screen can be reduced, and brightness and chromaticity differences of a display screen can be effectively reduced. Since the reset voltages of the connected driving transistors are equal everywhere, no new defects will be caused when the reset voltage is adjusted, so that the reset voltage has a greater adjustment range, which can effectively improve the interest of the display screen.

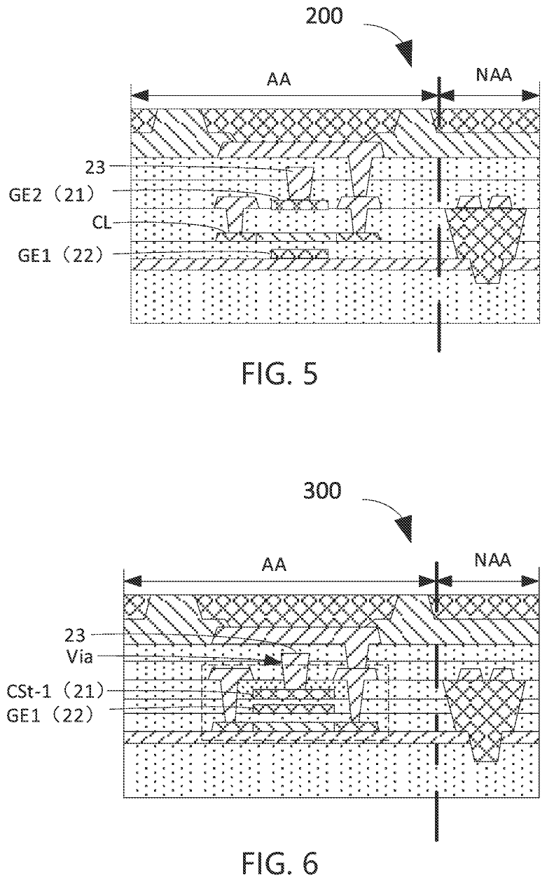

Refer to FIG. 5, the present application further provides a second embodiment of the flexible display 200. A structure of the flexible display 200 is substantially same as the structure of the flexible display 100, and the only difference lies in the structure of the dual-gate thin film transistor. The channel layer CL is positioned between the top gate GE2 and the bottom gate GE1. An equivalent circuit diagram of the present embodiment is same as that of the first embodiment.

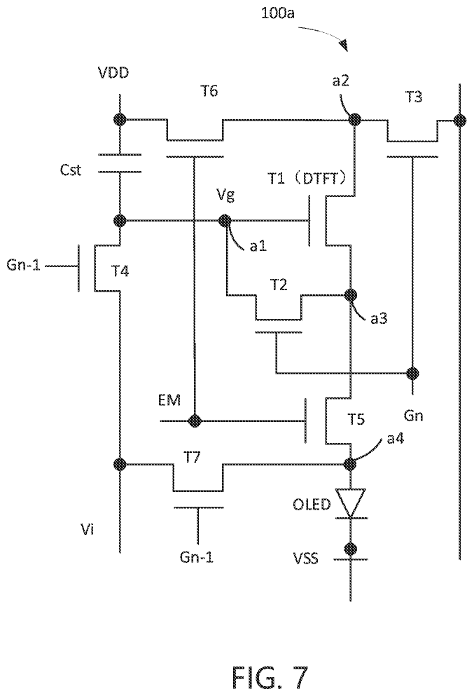

Refer to FIGS. 6 and 7, the present application further provides a third embodiment of the flexible display 300. A structure of the flexible display 300 is substantially same as the structure of the flexible display 100, and the only difference lies in the driving transistor DTFT is a single-gate thin film transistor with only one gate GE1. From a perspective of the equivalent circuit diagram shown in FIG. 7, the reset capacitor 20C is the storage capacitor Cst electrically connected to the driving transistor DTFT. The first reset electrode 21 is an upper electrode plate Cst-1 of the storage capacitor Cst. The second reset electrode 22 is the gate GE1, that is, the gate GE1 is a lower electrode plate Cst-2 of the storage capacitor Cst. A position of the upper electrode plate Cst-1 of the storage capacitor Cst is not limited in the present application. In an embodiment, the upper electrode plate Cst-1 of the storage capacitor Cst is positioned between the gate GE1, and the source SE and the drain DE. In another embodiment, the upper electrode plate Cst-1 of the storage capacitor Cst is positioned on a same level as the source SE and the drain DE. The upper electrode plate Cst-1 of the storage capacitor Cst is disposed opposite to the lower electrode plate Cst-2 of the storage capacitor Cst.

In the present embodiment, the driving transistor DTFT is the single-gate thin film transistor with only one gate GE1. By using the upper electrode plate Cst-1 of the storage capacitor Cst as the first reset electrode 21, it can also be a same technical effect as the first embodiment.

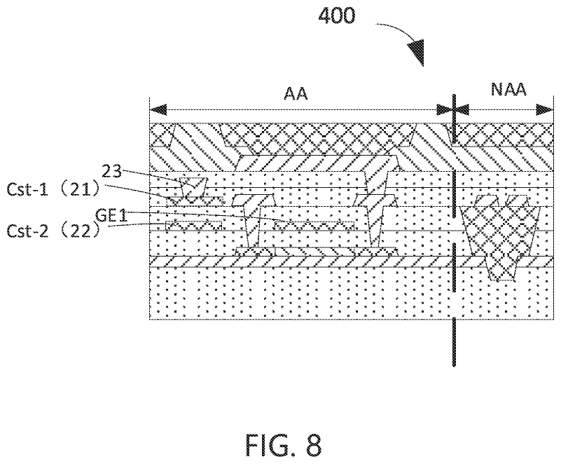

Refer to FIG. 8, the present application further provides a fourth embodiment of the flexible display 400. The equivalent circuit diagram of the present embodiment is same as shown in FIG. 7. From the perspective of the equivalent circuit diagram shown in 7, the reset capacitor 20C is the storage capacitor Cst electrically connected to the driving transistor DTFT. The first reset electrode 21 is the upper electrode plate Cst-1 of the storage capacitor Cst. A structure of the flexible display 400 is substantially same as the structure of the flexible display 300, and the only difference is that the upper electrode plate Cst-1 and the lower electrode plate Cst-2 of the storage capacitor Cst are both arranged independently of the gate GE1. The gate GE1 is not the lower electrode plate Cst-2 of the storage capacitor Cst, and the second reset electrode 22 is the lower electrode plate Cst-2 of the storage capacitor Cst. However, the lower electrode plate Cst-2 of the storage capacitor Cst is electrically connected to the gate GE1. Positions of the upper electrode plate Cst-1 of the storage capacitor Cst and the lower electrode plate Cst-2 of the storage capacitor Cst are not limited in the present application. In an embodiment, the upper electrode plate Cst-1 of the storage capacitor Cst is positioned in a same level as the source SE and the drain DE. The lower electrode plate Cst-2 of the storage capacitor Cst and the gate GE1 are positioned on a same level.

The present document uses specific embodiments to explain principles and implementation of the application. They are only used to help understand technical solutions and ideas of the application. A person skilled in the art can make various modifications and changes to the above embodiments without departing from the technical idea of the present invention, and such variations and modifications are intended to be within the scope of the invention. In summary, the content of the present specification should not be construed as a limitation to the present application.

1. A flexible display, comprising a substrate and a plurality of sub-pixels arranged on the substrate,
wherein each of the sub-pixels is provided with a unit driving circuit, each of the unit driving circuit comprises a driving transistor and a reset capacitor, each of the driving transistor comprises a gate, a channel layer, a source, and a drain, the reset capacitor comprises a first reset electrode and a second reset electrode arranged oppositely, the reset electrode is arranged on a side of the gate facing the source and the drain, and the second reset electrode is the gate or is electrically connected to the gate, and
wherein the flexible display comprises a transparent portion and a metal interconnection layer formed in an interconnection region around the transparent portion, and the metal interconnection layer is electrically connected to the first reset electrode of the unit driving circuit of each of the sub-pixels positioned in the interconnection region.

2. The flexible display according to claim 1, wherein the metal interconnection layer is disposed on a side of the driving transistor away from the substrate, and is electrically connected to the first reset electrode of the unit driving circuit of each of the sub-pixels positioned in the interconnection region through a via hole.

3. The flexible display according to claim 1, wherein the driving transistor is a dual-gate thin film transistor, the first reset electrode is a top gate of the dual-gate thin film transistor, and the second reset electrode is a bottom gate of the dual-gate thin film transistor.

4. The flexible display according to claim 3, wherein the bottom gate is positioned between the top gate and the channel layer.

5. The flexible display according to claim 4, wherein the source and the drain are positioned between the metal interconnection layer and the top gate.

6. The flexible display according to claim 4, wherein the metal interconnection layer is provided on a same level as the source and the drain of the driving transistor.

7. The flexible display according to claim 3, wherein the channel layer is positioned between the top gate and the bottom gate.

8. The flexible display according to claim 1, wherein the reset capacitor is a storage capacitor electrically connected to the driving transistor, and the first reset electrode is an upper electrode plate of the storage capacitor.

9. The flexible display according to claim 8, wherein the second reset electrode is the gate, and the gate is a lower electrode plate of the storage capacitor.

10. The flexible display according to claim 9, wherein the upper electrode plate of the storage capacitor is positioned between the gate and the source and the drain.

11. The flexible display according to claim 9, wherein the upper electrode plate of the storage capacitor is positioned on a same level as the source and the drain.

12. The flexible display according to claim 8, wherein the second reset electrode is a lower electrode plate of the storage capacitor, and the lower electrode plate of the storage capacitor is electrically connected to the gate.

13. The flexible display according to claim 12, wherein the upper electrode plate of the storage capacitor is positioned on a same level as the source and the drain, and the lower electrode plate of the storage capacitor is positioned on a same level as the gate.

14. The flexible display according to claim 1, wherein the metal interconnection layer comprises a metal grid pattern, and an orthographic projection of the metal grid pattern on a plane of a power voltage line overlaps a pattern formed by the power voltage line.

15. The flexible display according to claim 14, wherein the metal grid pattern comprises a plurality of vertices and a plurality of connection lines connected between adjacent two of the vertices, the vertices are distributed in an array, and the vertices are arranged in a zigzag shape in a first direction, and are arranged in a straight line in a second direction.

16. The flexible display according to claim 15, wherein each of the vertices of the metal grid pattern is electrically connected to one of the first reset electrode.

17. The flexible display according to claim 14, wherein the metal grid pattern comprises a plurality of connection lines, the connection lines and a reset voltage line are manufactured by a same process and have a same line width.
